(19) United States
(12) Patent Application Publication
(10) Pub. No.: US 2025/0357312 A1
(43) Pub. Date: Nov. 20, 2025

(54) METAL-INSULATOR-METAL (MIM) CAPACITORS WITH IMPROVED RELIABILITY

(71) Applicant: Taiwan Semiconductor Manufacturing Company, Ltd., Hsin-Chu (TW)

(72) Inventors: Chia-Yueh Chou, Taoyuan City (TW); Hsiang-Ku Shen, Hsinchu City (TW); Chen-Chiu Huang, Taichung City (TW); Dian-Hau Chen, Hsinchu (TW); Cheng-Hao Hou, Hsinchu City (TW); Kun-Yu Lee, Tainan City (TW); Ming-Ho Lin, Taipei City (TW); Alvin Universe Tang, Hsinchu City (TW); Chun-Hsiu Chiang, Taipei City (TW)

(21) Appl. No.: 19/288,591

(22) Filed: Aug. 1, 2025

Related U.S. Application Data
(63) Continuation of application No. 18/524,533, filed on Nov. 30, 2023.
(60) Provisional application No. 63/582,019, filed on Sep. 12, 2023.

(51) Int. Cl. H01L 23/522

(52) U.S. Cl. CPC H01L 23/5223

(57) ABSTRACT

Semiconductor structures and methods are provided. An exemplary method includes depositing forming a first metal-insulator-metal (MIM) capacitor over a substrate and forming a second MIM capacitor over the first MIM capacitor. The forming of the first MIM capacitor includes forming a first conductor plate over a substrate, the first conductor plate comprising a first metal element, conformally depositing a first dielectric layer on the first conductor plate, the first dielectric layer comprising the first metal element, forming a first high-K dielectric layer on the first dielectric layer, conformally depositing a second dielectric layer on the first high-K dielectric layer, the second dielectric layer comprising a second metal element, and forming a second conductor plate over the second dielectric layer, the second conductor plate comprises the second metal element.

### PRIORITY

The present application is a continuation application of U.S. patent application Ser. No. 18/524,533, filed on Nov. 30, 2023, which claims the benefit of U.S. Provisional Application No. 63/582,019, filed on Sep. 12, 2023, each of which is herein incorporated by reference in its entirety.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component that can be created using a fabrication process) has decreased.

As the geometry size of IC devices decreases, passive devices that require large surface areas are moved to back-end-of-line (BEOL) structures. Metal-insulator-metal (MIM) capacitors are among examples of such passive devices. A typical MIM capacitor includes multiple conductor plates that are insulated from one another by multiple insulator layers. Although existing MIM capacitors and the fabrication processes thereof have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a semiconductor structure, according to various aspects of the present disclosure.

FIGS. 2, 3, 4, 5, 6, 7, 8, 9, 10, 11, 12, 13, 14, and 15 illustrate fragmentary cross-sectional views of a semiconductor structure (or workpiece) during various fabrication stages in the method of FIG. 1, according to various aspects of the present disclosure.

FIG. 16 depicts a fragmentary cross-sectional view of a first alternative semiconductor structure, according to various aspects of the present disclosure.

FIGS. 17A, 17B, and 17C depict fragmentary cross-sectional view of second, third, and fourth alternative semiconductor structure, according to various aspects of the present disclosure.

FIG. 18 depicts a fragmentary cross-sectional view of a fifth alternative semiconductor structure, according to various aspects of the present disclosure.

FIG. 19A and FIG. 19B depict fragmentary cross-sectional views of a fourth alternative semiconductor structure and a fifth alternative semiconductor structure, respectively according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Metal-insulator-metal (MIM) capacitors have been widely used in functional circuits such as mixed signal circuits, analog circuits, Radio Frequency (RF) circuits, Dynamic Random-Access Memories (DRAMs), and logic operation circuits. In system-on-chip (SOC) applications, different capacitors for different functional circuits have to be integrated on a same chip to serve different purposes. For example, in mixed-signal circuits, capacitors are used as decoupling capacitors and high-frequency noise filters. For DRAM and embedded DRAM circuits, capacitors are used for memory storage, while for RF circuits, capacitors are used in oscillators and phase-shift networks for coupling and/or bypassing purposes. For microprocessors, capacitors are used for decoupling. Nowadays, MIM capacitors are also implemented in high-performance computing (HPC). Those MIM capacitors implemented in HPC may need high capacitances. As its name suggests, an MIM capacitor includes a sandwich structure of interleaving conductor plates and insulation layers. In an example, an MIM capacitor includes multiple conductor plates, each of which is insulated from an adjacent conductor plate by an insulation layer. In some existing technologies, an MIM capacitor includes a first conductor plate, a high-K dielectric layer over and in direct contact with the first conductor plate, and a second conductor plate over and in direct contact with the high-K dielectric layer. The interface quality between the first/second conductor plate and the high-K dielectric layer encompasses factors such as oxygen vacancies, impurities, and/or dangling bonds that disadvantageously affect the time-dependence-dielectric-breakdown (TDDB) performance of the MIM capacitor. For example, for embodiments in which the high-K dielectric layer includes oxygen element (e.g., hafnium-zirconium oxide (HZO)) and the first/second conductor plate includes metal element, the metal from the first/second conductor plate and the oxygen from the high-K dielectric layer may react to form a non-stoichiometric metal oxide layer at the interface between the first/second conductor plate and the high-K dielectric layer. This non-stoichiometric metal oxide layer may contain vacancies and has a poor film quality, which disadvantageously affect the TDDB performance of the MIM capacitor. Although existing MIM capacitors may be generally satisfactory in providing high capacitances, they may have short lifetime since the insulation layers (e.g., the non-stoichiometric metal oxide layer) disposed between two adjacent conductor plates undergo time-dependence-dielectric-breakdown (TDDB) failure.

The present disclosure provides metal-insulator-metal (MIM) capacitors having improved TDDB performance and methods of forming the same. In an exemplary embodiment, a method of forming the MIM capacitor includes depositing a first conductive layer over a substrate, performing an etching process to pattern the first conductive layer to form a first conductor plate, performing a first atomic layer deposition (ALD) process to form a first metal oxide layer on the first conductive layer, forming a high-K dielectric layer (e.g., hafnium-zirconium oxide (HZO) layer) over the ALD-formed first metal oxide layer, performing a second atomic layer deposition (ALD) process to form a second metal oxide layer over the high-K dielectric layer, and then forming a second conductor layer on the ALD-formed second metal oxide layer. The first metal oxide layer and the first conductor plate include the same metal element, and the second metal oxide layer and the second conductor layer include the same metal element. Forming the ALD-formed metal oxide layer between the conductor plate and the high-K dielectric layer may substantially prevent the formation of a non-stoichiometric metal oxide layer at the interface between the conductor plate and the high-K dielectric layer. Thus, TDDB performance of the MIM capacitor may be advantageously improved.

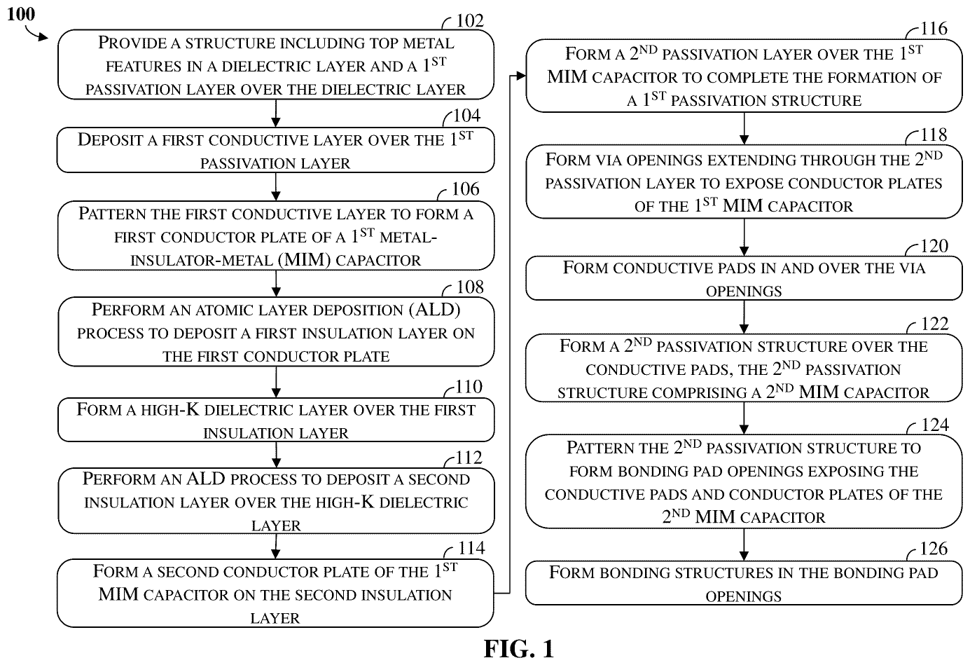

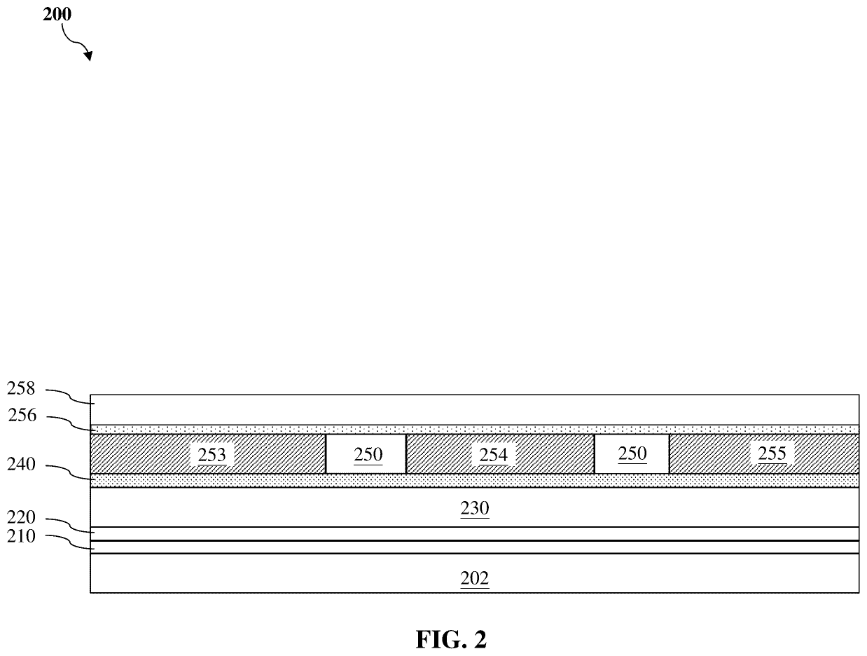

The various aspects of the present disclosure will now be described in more detail with reference to the figures. In that regard, FIG. 1 is a flowchart illustrating a method 100 for fabricating a semiconductor structure, according to embodiments of the present disclosure. Method 100 is described below in conjunction with FIGS. 2-16, 17A-17C, 18 and 19A-19B, which are fragmentary cross-sectional views of a workpiece 200 at different stages of fabrication according to embodiments of method 100. Because the workpiece 200 will be fabricated into a semiconductor structure at the conclusion of the fabrication processes, the workpiece may also be referred to as a semiconductor structure 200, as the context requires. Method 100 is merely an example and is not intended to limit the present disclosure to what is explicitly illustrated therein. Additional steps can be provided before, during, and after method 100, and some steps described can be replaced, eliminated, or moved around for additional embodiments of the method. Not all steps are described herein in detail for reasons of simplicity. Additionally, throughout the present application, like reference numerals denote like features, unless otherwise excepted.

Referring to FIGS. 1 and 2, method 100 includes a block 102 where a semiconductor structure 200 is provided. The semiconductor structure 200 includes a substrate 202, which may be made of silicon or other semiconductor materials such as germanium. The substrate 202 may also include a compound semiconductor such as silicon carbide, gallium arsenic, indium arsenide, or indium phosphide. In some embodiments, the substrate 202 may include alloy semiconductor such as silicon germanium, silicon germanium carbide, gallium arsenic phosphide, or gallium indium phosphide. In some embodiments, the substrate 202 may include an epitaxial layer, such as an epitaxial layer overlying a bulk semiconductor. Various microelectronic components may be formed in or on the substrate 202, such as transistor components including source/drain features, gate structures, gate spacers, source/drain contacts, gate contacts, isolation structures including shallow trench isolation (STI), or any other suitable components. Source/drain feature(s) may refer to a source or a drain, individually or collectively dependent upon the context. Transistors formed on the substrate 202 may be planar devices or multi-gate devices. Multi-gate devices include, for example, fin-like field effect transistors (FinFETs) or nanostructure transistors. A FinFET has an elevated channel wrapped by a gate on more than one side (for example, the gate wraps a top and sidewalls of a “fin” of semiconductor material extending from a substrate). A nanostructure transistor has a gate structure that can extend, partially or fully, around a channel region to provide access to the channel region on two or more sides. Because its gate structure surrounds the channel regions, a nanostructure transistor may also be referred to as a gate-all-around (GAA) transistor.

The semiconductor structure 200 also includes a multi-layer interconnect (MLI) structure 210, which provides interconnections (e.g., wiring) between the various microelectronic components of the semiconductor structure 200. The MLI structure 210 may also be referred to as an interconnect structure 210. The MLI structure 210 may include multiple metal layers or metallization layers. In some instances, the MLI structure 210 may include eight (8) to fourteen (14) metal layers. Each of the metal layers includes multiple conductive components embedded in an intermetal dielectric (IMD) layer. The conductive components may include contacts, vias, or metal lines. The IMD layer may be a silicon oxide or silicon-oxide-containing material where silicon exists in various suitable forms. As an example, the IMD layer includes silicon oxide or a low-k dielectric material having k-value (dielectric constant) smaller than that of silicon oxide, which is about 3.9. In some embodiments, the low-k dielectric material includes tetraethylorthosilicate (TEOS) oxide, un-doped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), spin-on silicon based polymeric dielectrics, combinations thereof, or other suitable materials. The conductive components may be formed of any suitable conductive materials.

In an embodiment, the semiconductor structure 200 also includes a carbide layer 220 deposited on the MLI structure 210. The deposition process includes chemical vapor deposition (CVD), physical vapor deposition (PVD), atomic layer deposition (ALD), or combinations thereof. Any suitable type of carbide material such as silicon carbide (SiC) can be used in the carbide layer 220. In an embodiment, an oxide layer 230 is deposited on the carbide layer 220. Any suitable deposition process for the oxide layer 230 may be used, including CVD, flowable CVD (FCVD), spin-on coating, PVD, ALD, or combinations thereof. In an embodiment, the oxide layer 230 includes undoped silicon oxide.

The semiconductor structure 200 also includes an etch stop layer (ESL) 240 disposed on the oxide layer 230. The ESL 240 may include silicon carbonitride (SiCN), silicon oxycarbide (SiOC), silicon carbide (SiC), silicon oxycarbonitride (SiOCN), or silicon nitride (SiN), or combinations thereof and may be formed by chemical vapor deposition (CVD), physical vapor deposition (PVD), atomic layer deposition (ALD), or combinations thereof.

The semiconductor structure 200 also includes a dielectric layer 250 deposited on the ESL 240. A composition of the dielectric layer 250 may be similar to that of the oxide layer 230. In some embodiments, the dielectric layer 250 includes undoped silica glass (USG) or silicon oxide. The dielectric layer 250 may be deposited using CVD, flowable CVD (FCVD), spin-on coating, PVD, ALD, or combinations thereof.

The semiconductor structure 200 also includes a number of lower contact features (e.g., a lower contact feature 253, a lower contact feature 254, and a lower contact feature 255) formed in the dielectric layer 250. The formation of the lower contact features may include patterning of the dielectric layer 250 to form trenches and deposition of a barrier layer and a metal fill layer in the trenches. In some embodiments, the barrier layer may include titanium nitride or tantalum nitride and may be conformally deposited using PVD, CVD, metalorganic CVD (MOCVD), or a suitable method. In one embodiment, the barrier layer may include tantalum nitride. The metal fill layer includes a metal or metal alloy such as copper (Cu), cobalt (Co), nickel (Ni), aluminum (Al), tungsten (W), ruthenium (Ru), titanium (Ti), or combinations thereof. After the barrier layer and the metal fill layer are deposited, a planarization process, such as a chemical mechanical planarization (CMP) process, may be performed to remove excess portions of barrier layer and metal fill layer to form the lower contact features 253, 254 and 255. Although the lower contact features 253, 254, and 255 are disposed below upper conductive pads (such as conductive pads 280a and 280b), the lower contact features 253, 254, and 255 are sometimes referred to as top metal (TM) contacts 253, 254, and 255, respectively.

The semiconductor structure 200 also includes an etch stop layer 256 formed directly on the dielectric layer 250. In an embodiment, the etch stop layer 256 is deposited on the dielectric layer 250 by chemical vapor deposition (CVD), physical vapor deposition (PVD), atomic layer deposition (ALD), or combinations thereof. The etch stop layer 256 may include silicon carbonitride (SiCN), silicon nitride (SiN), other suitable materials, or combinations thereof. In the present embodiments, the etch stop layer 256 is in direct contact with top surfaces of the lower contact features 253, 254, and 255.

The semiconductor structure 200 also includes a first passivation layer 258 deposited over the etch stop layer 256. The first passivation layer 258 may include any suitable material (e.g., silicon nitride) and may be deposited using plasma-enhanced CVD (PECVD). Gaseous precursors used to form the first passivation layer 258 may include ammonia (NH₃), silane (SiH₄), and nitrogen (N₂).

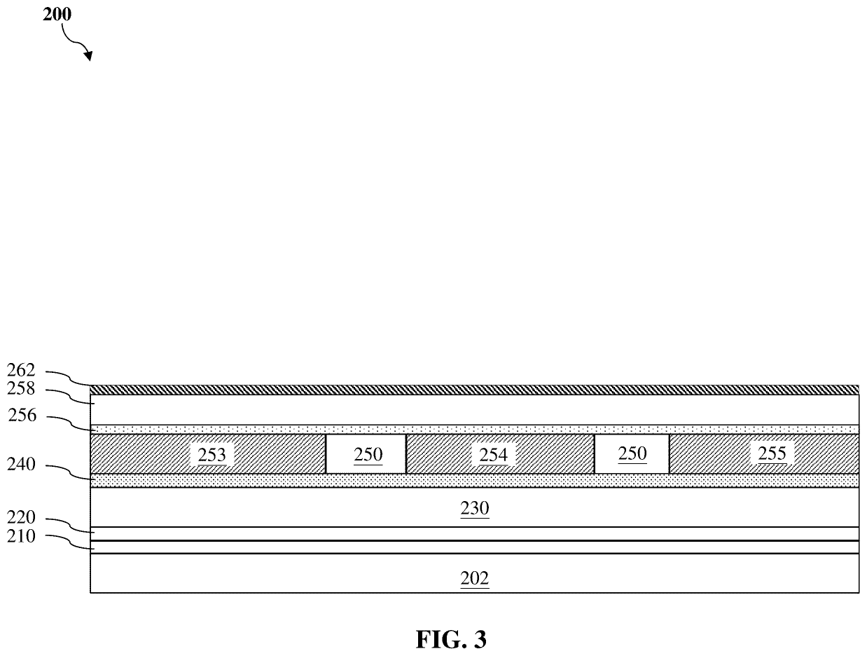

Referring to FIGS. 1 and 3, method 100 includes a block 104 where a first conductive layer 262 is deposited over the first passivation layer 258. The first conductive layer 262 may be deposited on the first passivation layer 258 using PVD, CVD, ALD, or MOCVD. In some embodiments, the first conductive layer 262 may include titanium (Ti), tantalum (Ta), titanium nitride (TiN), tantalum nitride (TaN), copper (Cu), cobalt (Co), nickel (Ni), tungsten (W), aluminum (Al), or other suitable materials.

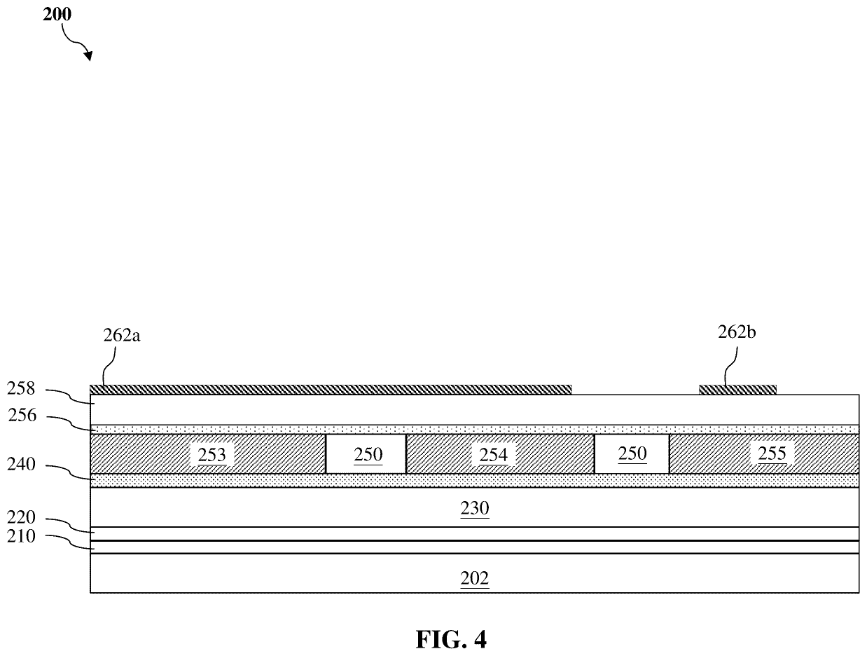

Referring to FIGS. 1 and 4, method 100 includes a block 106 where the first conductive layer 262 is patterned to form a first conductor plate 262a and a dummy conductive feature 262b. In the depicted example, the first conductor plate 262a is disposed directly over the lower contact feature 253, and the dummy conductive feature 262b is disposed directly over the lower contact feature 255. The patterning may include deposition of a hard mask layer over the first conductive layer 262, formation of a photoresist layer over the hard mask layer, patterning of the photoresist layer using photolithography, etching of the hard mask layer using the patterned photoresist layer as an etch mask, and then etching of the first conductive layer 262 using the patterned hard mask as an etch mask. The hard mask layer may be selectively removed after forming the first conductor plate 262a and the dummy conductive feature 262b.

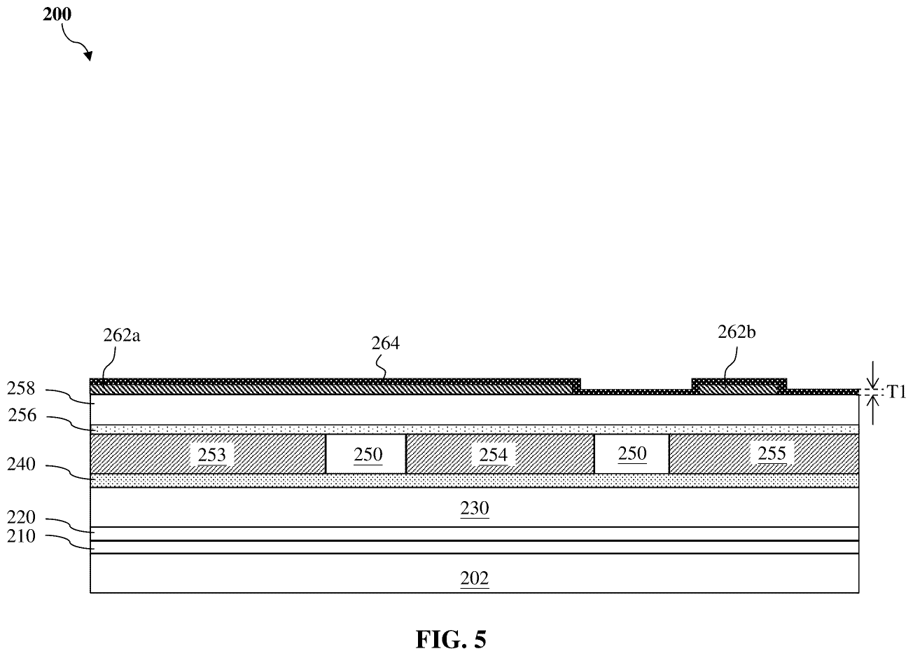

Referring to FIGS. 1 and 5, method 100 includes a block 108 where a first insulation layer 264 is deposited on the first conductor plate 262a. In the present embodiments, the first insulation layer 264 is conformally deposited over the semiconductor structure 200 to have a generally uniform thickness T1 over the top surface of the semiconductor structure 200 (e.g., having about the same thickness on top and sidewall surfaces of the first conductor plate 262a and the dummy conductive feature 262b). In an embodiment, an atomic layer deposition (ALD) process is performed to form the first insulation layer 264 with high film quality. To reduce lattice mismatch and reduce film lamination, the first insulation layer 264 and the first conductor plate 262a have the same metal element. For example, for embodiments in which the first conductor plate 262a is formed of aluminum, the first insulation layer 264 is formed of aluminum oxide having a fixed stoichiometric ratio (i.e., Al₂O₃); for embodiments in which the first conductor plate 262a is formed of titanium nitride, the first insulation layer 264 is formed of titanium oxide having a fixed stoichiometric ratio (i.e., TiO₂).

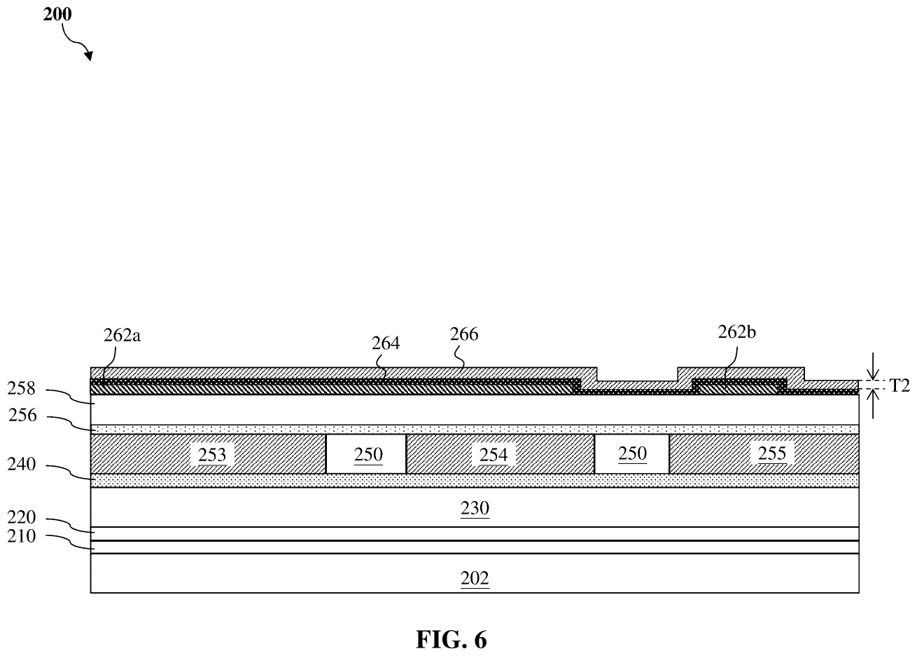

Referring to FIGS. 1 and 6, method 100 includes a block 110 where a high-K dielectric layer 266 is deposited over the first insulation layer 264. In some embodiments, the high-K dielectric layer 266 is conformally formed to have a generally uniform thickness T2 over the top surface of the semiconductor structure 200 (e.g., having about the same thickness on top and sidewall surfaces of the first insulation layer 264). In an embodiment, the high-K dielectric layer 266 includes hafnium-zirconium oxide (HZO) and is deposited using thermal atomic layer deposition (ALD) implementing halide precursors at a temperature between about 200° C. and about 400° C. The high-K dielectric layer 266 may include any other suitable materials. In the present embodiments, the high-K dielectric layer 266 is spaced apart from the first conductor plate 262a by the first insulation layer 264. To enhance forward bias related TDDB without substantially increasing the distance between two adjacent conductor plates to reduce a capacitance of the MIM capacitor, a ratio of the thickness T1 to the thickness T2 may be in a range between about 1/10 and about 1/2. If the ratio is greater than 1/2, the distance between two adjacent conductor plates will be significantly increased, leading to a large decrease in the capacitance of the first MIM capacitor 272. If the ratio is less than 1/10, the first insulation layer 264 may be not able to prevent or substantially reduce the chemical reaction between the first conductor plate 262a and the high-K dielectric layer 266 to prevent the formation of the native non-stoichiometric metal oxide layer that has a poor film quality to substantially improve the TDDB related performance.

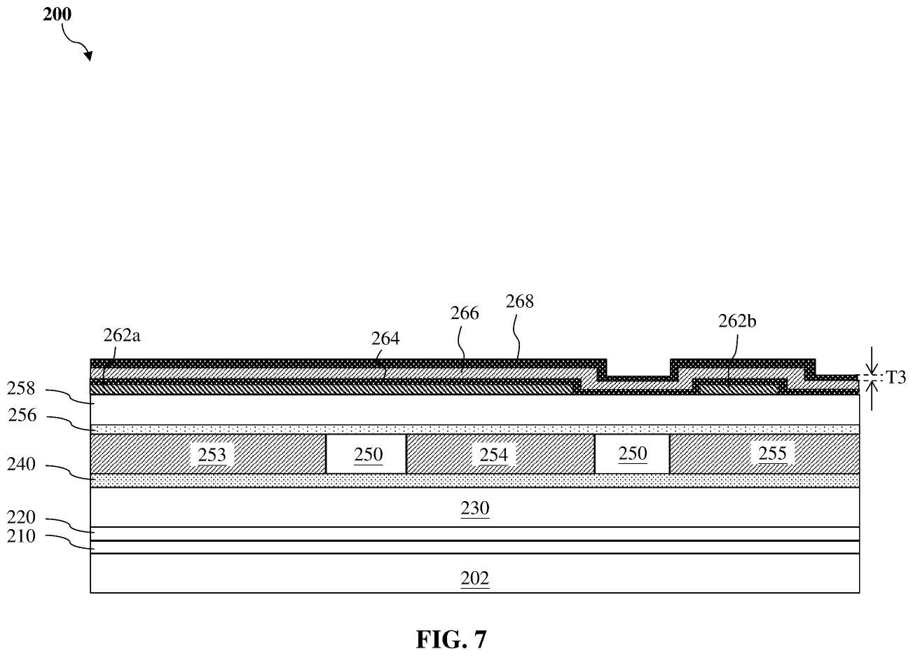

Referring to FIGS. 1 and 7, method 100 includes a block 112 where a second insulation layer 268 is deposited over the high-K dielectric layer 266. In the present embodiments, the second insulation layer 268 is conformally deposited over the semiconductor structure 200 to have a generally uniform thickness T3 over the top surface of the semiconductor structure 200 (e.g., having about the same thickness over top and sidewall surfaces of the high-K dielectric layer 266). In an embodiment, an ALD process is performed to form the second insulation layer 268 with high film quality. To reduce lattice mismatch and thus reduce film lamination, the second insulation layer 268 and the second conductor plate 270 that will be formed on the second insulation layer 268 have the same metal element. For example, for embodiments in which the second conductor plate 270 is formed of aluminum, the second insulation layer 268 is formed of aluminum oxide having a fixed stoichiometric ratio (i.e., Al₂O₃); for embodiments in which the second conductor plate 270 is formed of titanium nitride, the second insulation layer 268 is formed of titanium oxide having a fixed stoichiometric ratio (i.e., TiO₂). For similar reasons stated above, a ratio of the thickness T3 to the thickness T2 may be in a range between about 1/10 and about 1/2. In an embodiment, the thickness T3 is substantially equal to the thickness T1.

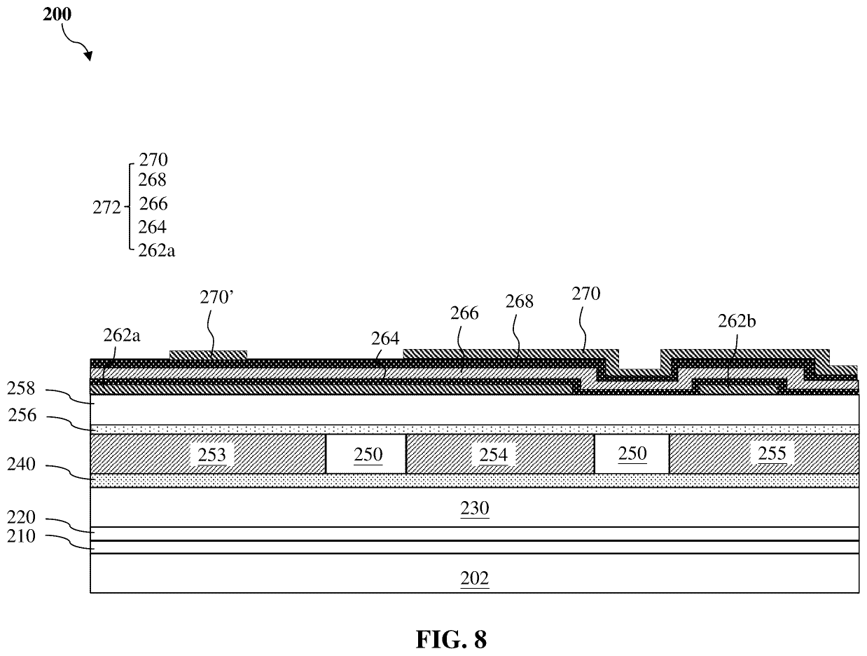

Referring to FIGS. 1 and 8, method 100 includes a block 114 where a second conductor plate 270 is formed on the second insulation layer 268. The second conductor plate 270 is vertically overlapped with the first conductor plate 262a and is spaced apart from the high-K dielectric layer 266 by the second insulation layer 268. A composition and formation of the second conductor plate 270 may be similar to those of the first conductor plate 262a. For example, a conductive layer may be deposited on second insulation layer 268 using PVD, CVD, ALD, or MOCVD and may include titanium (Ti), tantalum (Ta), titanium nitride (TiN), tantalum nitride (TaN), copper (Cu), cobalt (Co), nickel (Ni), tungsten (W), aluminum (Al), or other suitable materials. The conductive layer is then patterned to form the second conductor plate 270 and a dummy conductive feature 270′. In an embodiment, the second conductor plate 270 is formed of aluminum. In another embodiment, the second conductor plate 270 is formed of titanium nitride. After the formation of the second conductor plate 270, the structure of a MIM capacitor 272 is finalized. It is understood that the first MIM capacitor 272 may have different configurations. For example, the first MIM capacitor 272 may include other suitable number of conductor plates (e.g., three, four, or more), and each of the conductor plate is isolated from a high-K dielectric layer by an ALD-formed metal oxide layer that contains a metal element same to the corresponding conductor plate.

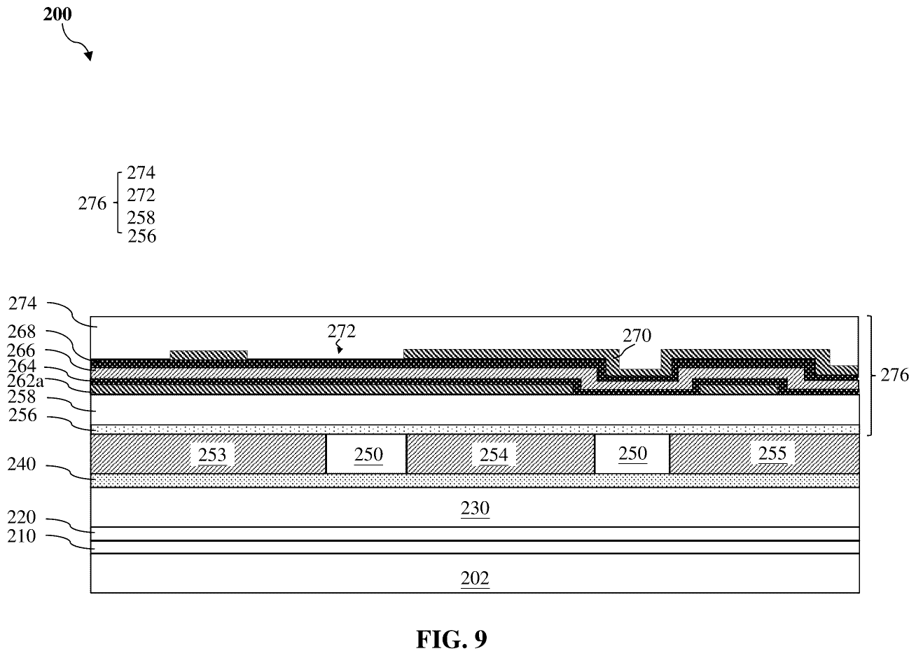

Referring to FIGS. 1 and 9, method 100 includes a block 116 where a second passivation layer 274 is formed over the first MIM capacitor 272. In some embodiments, the second passivation layer 274 may include a dielectric layer or two or more dielectric layers formed by any suitable materials such as silicon oxide or silicon nitride and may be formed by any suitable deposition processes (e.g., plasma-enhanced chemical vapor deposition (PECVD)). As shown in FIG. 9, the first MIM capacitor 272 is sandwiched between the second passivation layer 274 and first passivation layer 258. The first passivation layer 258 and the second passivation layer 267 protect the first MIM capacitor 272 from damages due to stress or crack propagation. In some embodiments, the etch stop layer 256, the first passivation layer 258, the first MIM capacitor 272, and the second passivation layer 274 may be collectively referred to as a first passivation structure 276.

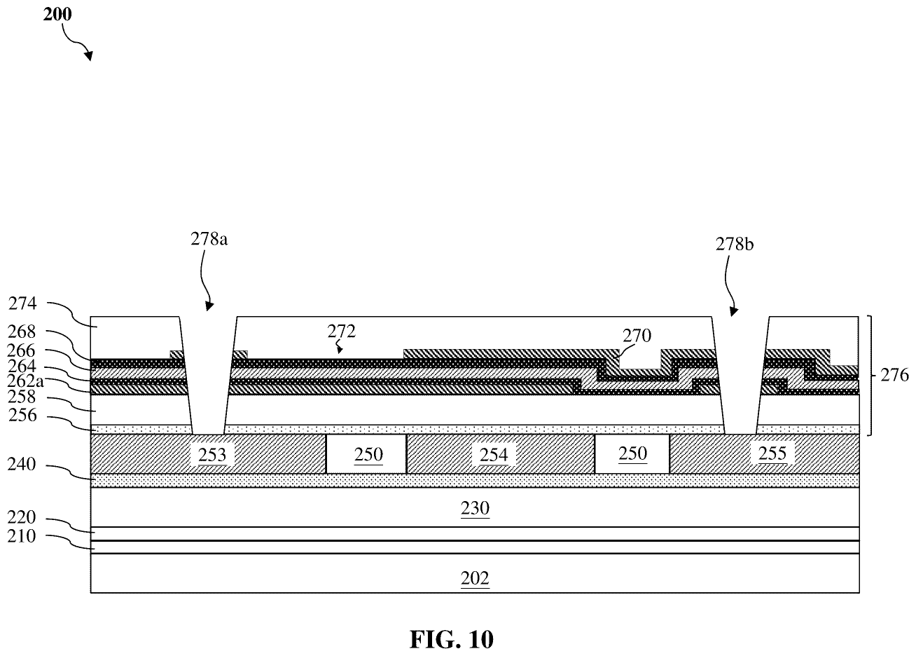

Referring to FIGS. 1 and 10, method 100 includes a block 118 where a number of via openings (such as via openings 278a, 278b) are formed to penetrate through the first passivation structure 276. In the depicted embodiment, the via opening 278a extends through the second passivation layer 274, the dummy conductive feature 270′, the second insulation layer 268, the high-K dielectric layer 266, the first insulation layer 264, the first conductor plate 262a, the first passivation layer 258, and the etch stop layer 256 to expose the lower contact feature 253. The via opening 278a extends through the second passivation layer 274, the second conductor plate 270, the second insulation layer 268, the high-K dielectric layer 266, the first insulation layer 264, the dummy conductive layer 262b, the first passivation layer 258, and the etch stop layer 256 to expose the lower contact feature 255. The formation of the via openings (such as via openings 278a, 278b) involves performing a combination of lithography and etching processes. In an embodiment, the via openings 278a and 278b may be formed using dry etching, such as reactive ion etching (RIE). In some embodiments, the formation of the via openings 278a and 278b may include use of oxygen, an oxygen-containing gas, hydrogen, a fluorine-containing gas (e.g., CF₄, SF₆, NF₃, BF₃, CH₂F₂, CHF₃, CH₃F, C₄H₈, C₄F₆, and/or C₂F₆), a carbon-containing gas (e.g., CO, CH₄, and/or C₃H₈), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof.

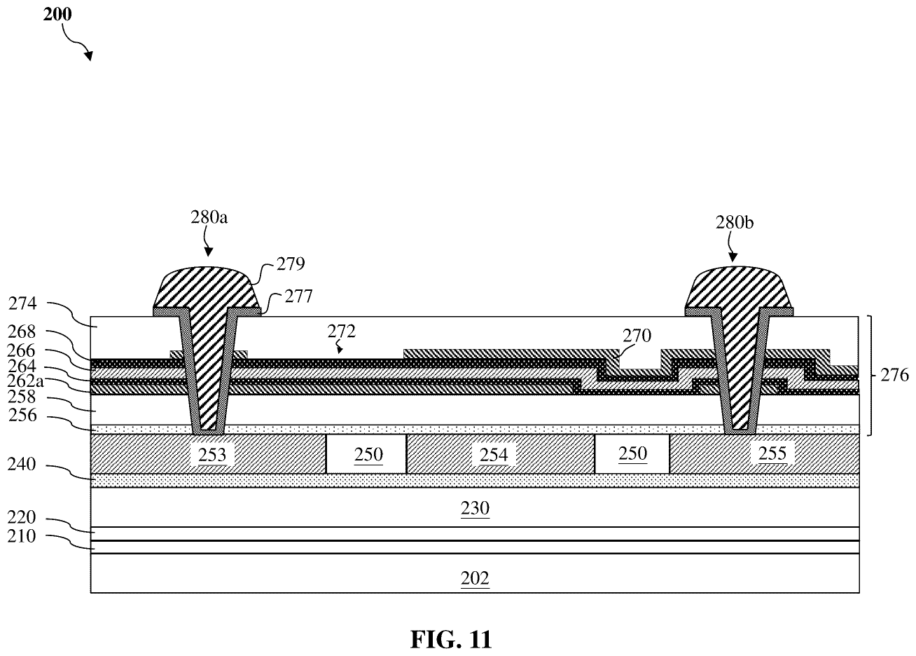

Referring to FIGS. 1 and 11, method 100 includes a block 120 where conductive pads (such as conductive pads 280a and 280b) are formed in and over the via openings (such as the via openings 278a and 278b). In an example process, a barrier layer 277 is first conformally deposited over the second passivation layer 274 and into the via openings 278a and 278b using a suitable deposition technique, such as ALD, PVD or CVD and then a metal fill layer 279 is deposited over the barrier layer 277 using ALD, PVD, CVD, electroless plating, or electroplating. The barrier layer 277 may include titanium nitride (TiN), tantalum nitride (TaN), or another metal nitride. The metal fill layer 279 may be formed of copper (Cu), aluminum (Al), aluminum copper (Al—Cu), or other suitable materials. In an embodiment, the metal fill layer 279 includes aluminum (Al), the barrier layer 277 includes tantalum nitride (TaN). A planarization process (e.g., CMP) may be then performed after depositing the metal fill layer 279. The barrier layer 277 and the metal fill layer 279 may be then patterned to form a number of conductive pads (such as conductive pads 280a and 280b) in and over the second passivation layer 274. In an example process, a photoresist layer may be formed over the barrier layer 277 and the metal fill layer 279 and then patterned, an etching process may be then performed to form the conductive pads 280a and 280b while using the patterned photoresist layer as an etch mask. In some embodiments, the conductive pads (such as conductive pads 280a and 280b) may be referred to as upper contact features or upper conductive pads and may be part of a redistribution layer (RDL) to reroute bond connections between upper and lower layers.

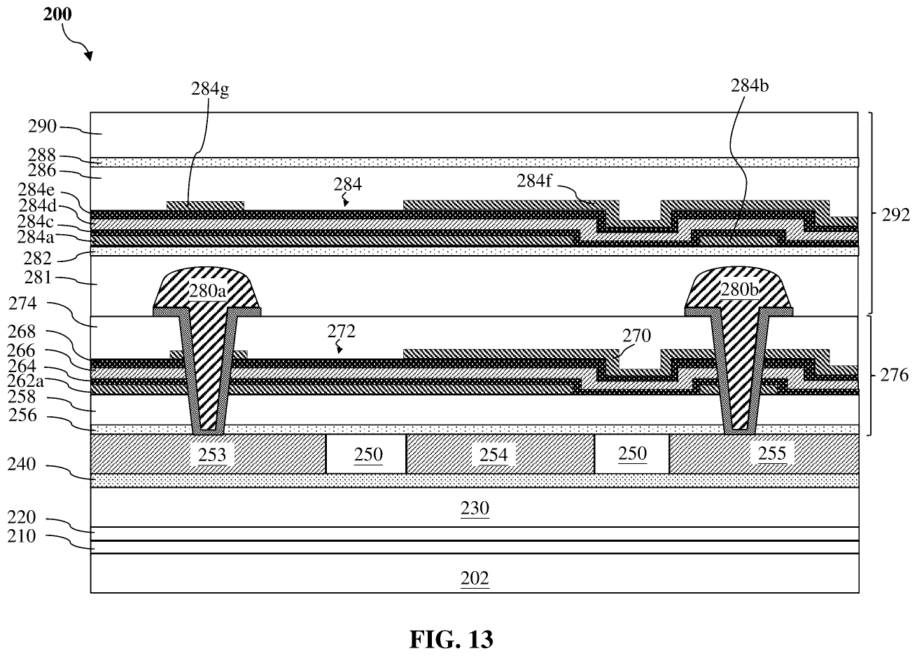

Referring to FIGS. 1 and 12-13, method 100 includes a block 122 where a second passivation structure 292 is formed over the conductive pads 280a and 280b. In the present embodiments, the second passivation structure 292 (shown in FIG. 13) is a multi-layer structure. More specially, the second passivation structure 292 includes a third passivation layer 281 (e.g., silicon nitride formed by CVD, PECVD, or a suitable method) disposed over the conductive pads 280a and 280b. A planarization process may be performed to the third passivation layer 281 to provide a planar top surface. After forming the third passivation layer 281, an etch stop layer 282 is formed directly on the third passivation layer 281. In an embodiment, the etch stop layer 282 is deposited on the third passivation layer 281 by using chemical vapor deposition (CVD), physical vapor deposition (PVD), atomic layer deposition (ALD), or combinations thereof. The etch stop layer 282 may include silicon carbonitride (SiCN), silicon nitride (SiN), other suitable materials, or combinations thereof.

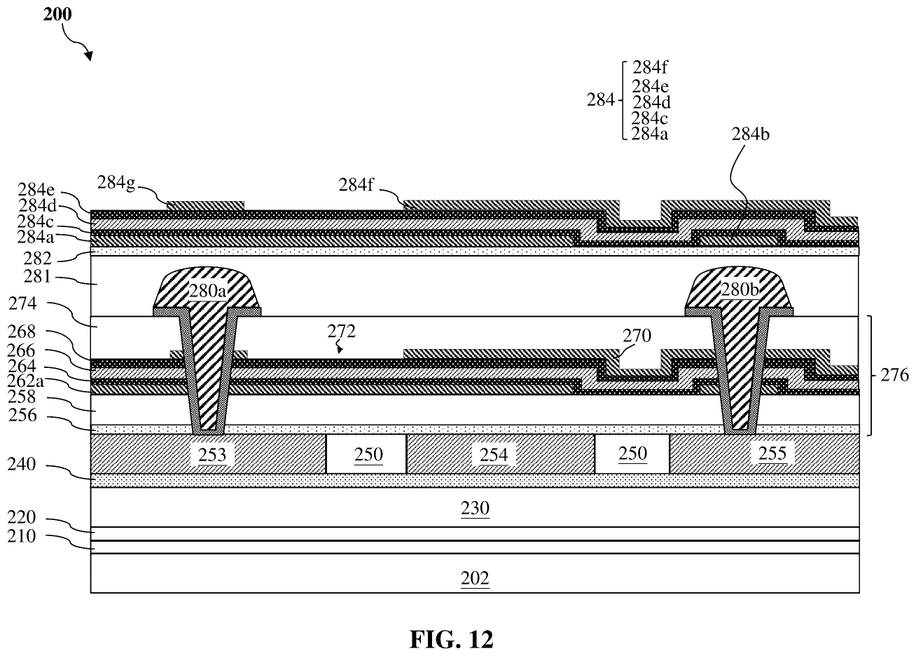

The second passivation structure 292 also includes a second MIM capacitor 284 (shown in FIG. 12) formed on the etch stop layer 282. In the illustrated embodiment, the formation and composition of the second MIM capacitor 284 are substantially similar to those of the MIM capacitor 272. More specifically, a conductive layer may be deposited over the etch stop layer 282 and then patterned to form a bottom conductor plate 284a and a dummy conductive feature 284b. In the depicted example, the bottom conductor plate 284a is disposed directly over the lower contact feature 253, and the dummy conductive feature 284b is disposed directly over the lower contact feature 255. The bottom conductor plate 284a may include titanium (Ti), tantalum (Ta), titanium nitride (TiN), tantalum nitride (TaN), copper (Cu), cobalt (Co), nickel (Ni), tungsten (W), aluminum (Al), or other suitable materials. An insulation layer 284c is conformally deposited on the bottom conductor plate 284a by performing an ALD process. To reduce lattice mismatch and thus reduce film lamination, the insulation layer 284c and the bottom conductor plate 284a have the same metal element. For example, for embodiments in which the bottom conductor plate 284a is formed of aluminum, the insulation layer 284c is formed of aluminum oxide having a fixed stoichiometric ratio (i.e., Al₂O₃); for embodiments in which the bottom conductor plate 284a is formed of titanium nitride, the insulation layer 284c is formed of titanium oxide having a fixed stoichiometric ratio (i.e., TiO₂).

After forming the insulation layer 284c, a high-K dielectric layer 284d is conformally deposited over the insulation layer 284c. In an embodiment, the high-K dielectric layer 284d includes hafnium-zirconium oxide (HZO) and is deposited using thermal atomic layer deposition (ALD) implementing halide precursors at a temperature between about 200° C. and about 400° C. The high-K dielectric layer 284d may include any other suitable materials. In the present embodiments, the high-K dielectric layer 284d is spaced apart from the bottom conductor plate 284a by the insulation layer 284c. To enhance forward bias related TDDB without substantially increasing the distance between two adjacent conductor plates to reduce a capacitance of the MIM capacitor, a ratio of the thickness of the insulation layer 284c to the thickness of the high-K dielectric layer 284d may be in a range between about 1/10 and about 1/2. If the ratio is greater than 1/2, the distance between two adjacent conductor plates will be significantly increased, leading to a large decrease in the capacitance of the second MIM capacitor 284. If the ratio is less than 1/10, the insulation layer 284c may be not thick enough to prevent or substantially reduce the formation of the native non-stoichiometric metal oxide layer that has a poor film quality to substantially improve the TDDB related performance.

The second MIM capacitor 284 also includes an insulation layer 284e conformally deposited over the high-K dielectric layer 284d by performing an ALD process. The second MIM capacitor 284 also includes a top conductor plate 284f and a dummy conductive layer 284g disposed on the insulation layer 284e. That is, the top conductor plate 284f is spaced apart from the high-K dielectric layer 284d by the insulation layer 284e. A composition and formation of the top conductor plate 284f may be similar to those of the first conductor plate 262a. To reduce lattice mismatch and thus reduce film lamination, the insulation layer 284e and the top conductor plate 284f have the same metal element. For example, for embodiments in which the top conductor plate 284f is formed of aluminum, the insulation layer 284e is formed of aluminum oxide having a fixed stoichiometric ratio (i.e., Al₂O₃); for embodiments in which the top conductor plate 284f is formed of titanium nitride, the insulation layer 284e is formed of titanium oxide having a fixed stoichiometric ratio (i.e., TiO₂). For similar reasons stated above, a ratio of the thickness of the insulation layer 284e to the thickness of the high-K dielectric layer 284d may be in a range between about 1/10 and about 1/2. It is understood that the second MIM capacitor 284 may have different configurations. For example, the second MIM capacitor 284 may include other suitable number of conductor plates (e.g., three, four, or more), and each of the conductor plate is isolated from a high-K dielectric layer by an ALD-formed metal oxide layer that contains a metal element same to the corresponding conductor plate.

With reference to FIG. 13, the formation of the second passivation structure 292 also includes forming a fourth passivation layer 286 over the second MIM capacitor 284. In an embodiment, the fourth passivation layer 286 is a low-k dielectric material and includes tetraethylorthosilicate (TEOS) oxide. The formation of the second passivation structure 292 also includes forming an etch stop layer 288 on the fourth passivation layer 286. In an embodiment, the etch stop layer 288 includes silicon carbonitride (SiCN) and/or silicon nitride (SiN) and is deposited on the fourth passivation layer 286 by using chemical vapor deposition (CVD), physical vapor deposition (PVD), atomic layer deposition (ALD). The formation of the second passivation structure 292 also includes forming a fifth passivation layer 290 over the etch stop layer 288. In some embodiments, the fifth passivation layer 290 is a low-k dielectric material. In an embodiment, the fifth passivation layer 290 includes tetraethylorthosilicate (TEOS) oxide. The third passivation layer 281, the etch stop layer 282, the second MIM capacitor 284, the fourth passivation layer 286, the etch stop layer 288 and the fifth passivation layer 290 are collectively referred to as the second passivation structure 292.

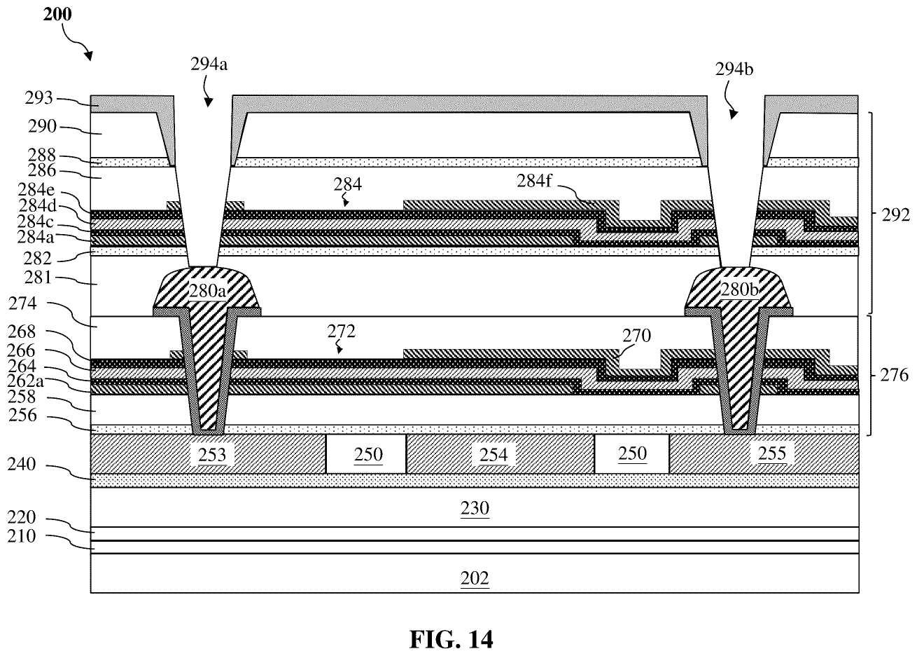

Referring to FIGS. 1 and 14, method 100 includes a block 124 where the second passivation structure 292 is patterned to form bonding pad openings (e.g., bonding pad openings 294a and 294b) to expose the conductive pads (e.g., the conductive pads 280a and 280b) and conductor plates (e.g., the conductor plates 284a and 284f) of the second MIM capacitor 284. In an example process, a combination of lithography and etching processes are performed to form openings extending through the fifth passivation layer 290 and the etch stop layer 288. The lithography process can include forming a resist layer (not shown) on the fifth passivation layer 290 (for example, by spin coating), performing a pre-exposure baking process, performing an exposure process using a mask, performing a post-exposure baking process, and performing a developing process. After development, the patterned resist layer includes a resist pattern that corresponds with the mask. While using the patterned resist layer as an etch mask, a first etching process is performed to to remove portions of the fifth passivation layer 290 and the etch stop layer 288. In an embodiment, the first etching process includes a dry etching process and it stops once the etch stop layer 288 is fully etched. After the performing of the first etching process, the patterned resist layer is removed from the semiconductor structure 200, for example, by a resist stripping process. Then, a patterned mask film 293 may be formed over a top surface of the patterned fifth passivation layer 290 and sidewall surfaces of patterned fifth passivation layer 290 and the etch stop layer 288. As depicted in FIG. 14, a portion of the patterned mask film 293 is formed over and in direct contact with a portion of a top surface of the fourth passivation layer 286. A second etching process may be then performed to the second passivation structure 292 to remove other portions of the second passivation structure 292 not covered by the patterned mask film 293 to expose top surfaces of the conductive pads 280a and 280b. The patterned mask film 293 may be then selectively removed, thereby finishing the formation of the bonding pad openings 294a and 294b.

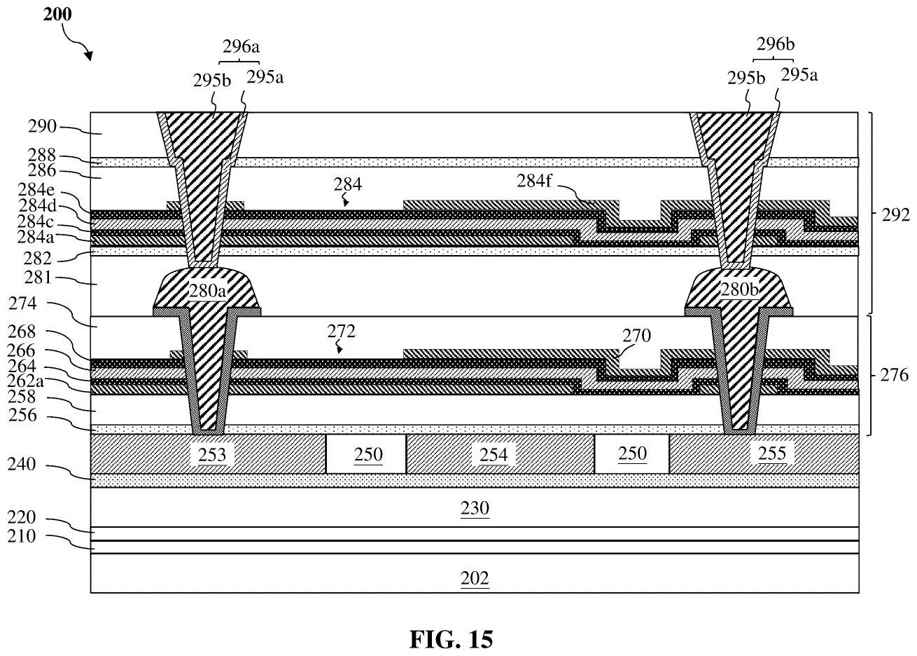

Referring to FIGS. 1 and 15, method 100 includes a block 126 where bonding structures 296a and 296b are formed in the bonding pad openings 294a and 294b, respectively. The formation of the bonding structures 296a and 296b may include conformally depositing a barrier layer 295a over the second passivation structure 292 and into the bonding pad openings 294a and 294b using a suitable deposition technique, such as ALD, PVD or CVD and then forming a metal fill layer 295b over the barrier layer 295a using ALD, PVD, CVD, electroless plating, or electroplating. The barrier layer 295a may include titanium nitride (TiN), tantalum nitride (TaN), or another metal nitride. The metal fill layer 295b may be formed of any suitable material, such as copper (Cu). After the deposition of the conductive material, a planarization process (e.g., CMP) may be then performed such that top surfaces of the metal fill layer 295b and barrier layer 295a are coplanar with the top surface of the second passivation structure 292. Portions of the bonding structures 296a and 296b formed in the lower portion (e.g., a portion that is over the fourth passivation layer 286) of the bonding pad openings 294a and 294b may be referred to as bonding pad vias (BPV), and portions of the bonding structures 296a and 296b formed in the upper portion (e.g., a portion that is under the etch stop layer 288) of the bonding pad openings 294a and 294b may be referred to as bonding pad metal lines (BPM). In the present embodiments, the bonding structure 296a extends through the bottom conductor plate 284a of the second MIM capacitor 284 and in direct contact with the conductive pad 280a which directly contacts the first conductor plate 262a of the first MIM capacitor 272. That is, the bottom conductor plate 284a of the second MIM capacitor 284 is electrically connected to the first conductor plate 262a of the first MIM capacitor 272. The bonding structure 296b extends through the top conductor plate 284f of the second MIM capacitor 284 and in direct contact with the conductive pad 280b which directly contacts the second conductor plate 270 of the first MIM capacitor 272. That is, the top conductor plate 284f of the second MIM capacitor 284 is electrically connected to the second conductor plate 270 of the first MIM capacitor 272. Thus, the first MIM capacitor 272 and the second MIM capacitor 284 are electrically connected with in parallel, thereby providing a larger capacitance.

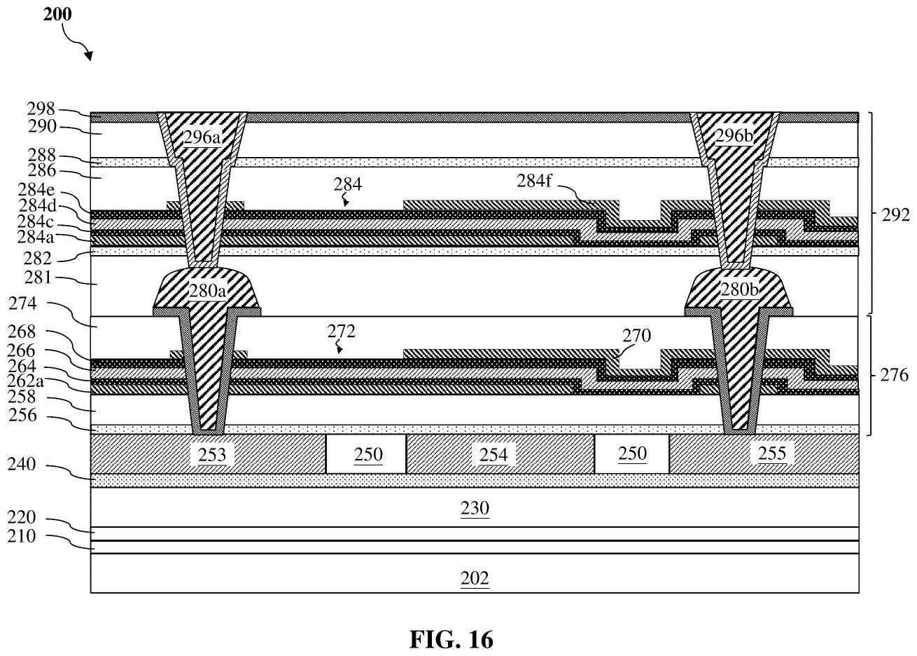

In the above embodiments, the second passivation structure 292 includes the third passivation layer 281, the etch stop layer 282, the second MIM capacitor 284, the fourth passivation layer 286, the etch stop layer 288, and the fifth passivation layer 290. In a first alternative embodiment represented by FIG. 16, the second passivation structure 292 also includes an anti-reflection layer 298 disposed on the fifth passivation layer 290. Forming the anti-reflection layer 298 may advantageously improve alignment during the formation of the bonding pad openings 294a and 294b. In some embodiments, the antireflection layer 298 is made of nitrogen-free material, such as silicon oxycarbide (SiOC), and the second passivation structure 292 (including the anti-reflection layer 298) may be then patterned to from the bonding pad openings 294a and 294b. The bonding structures 296a and 296b may be then formed in the bonding pad openings 294a and 294b. As depicted in FIG. 16, top surfaces of the bonding structures 296a and 296b are coplanar with the top surface of the anti-reflection layer 298.

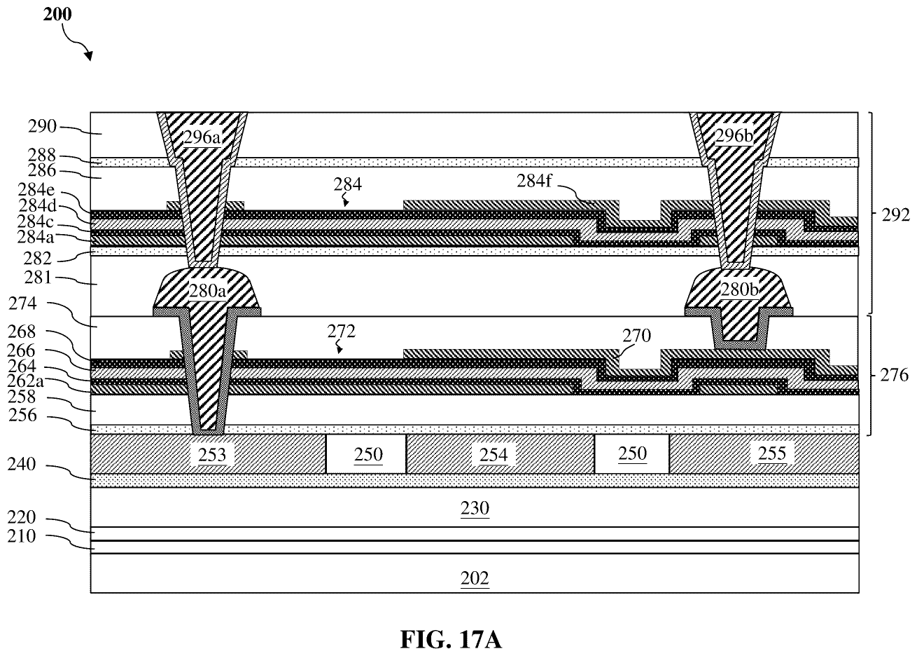

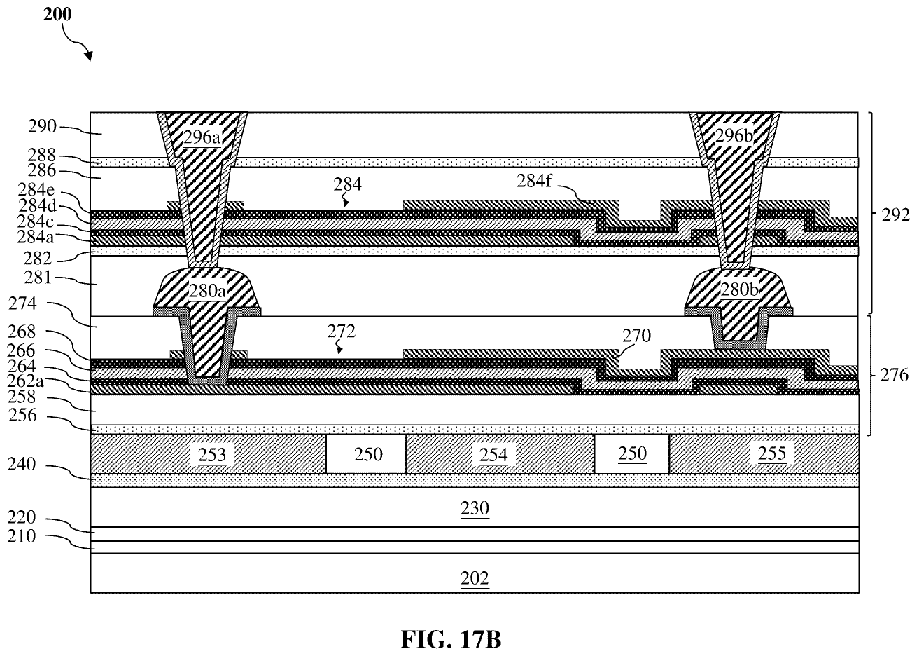

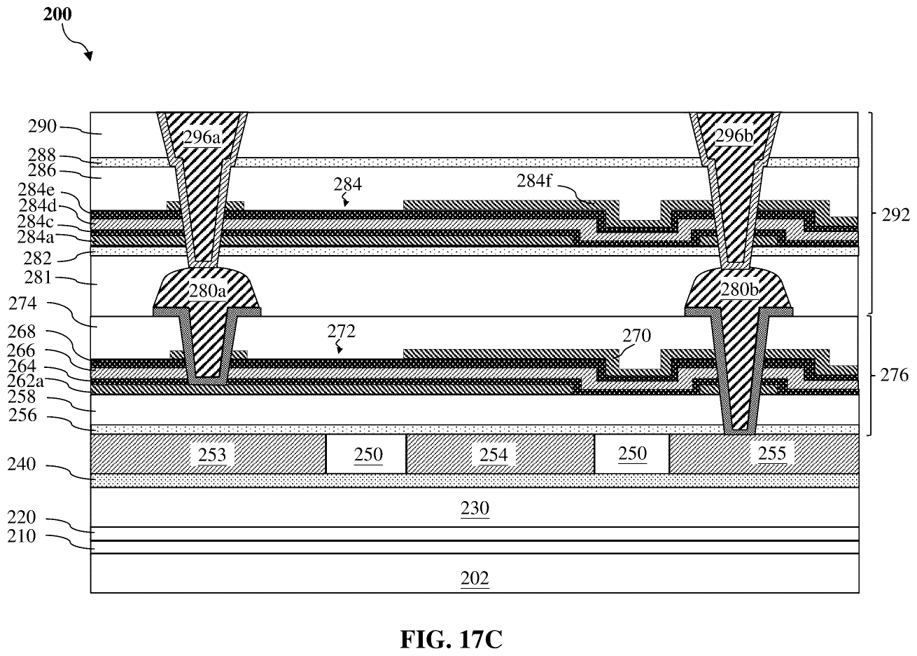

In the above embodiments, both the conductive pads 280a and 280b extend through the first passivation structure 276 and in direct contact with the corresponding top metal contacts (e.g., the top metal contacts 253 and 255). In a second alternative embodiment represented by FIG. 17A, the conductive pad 280a extends through the first passivation structure 276 and is in direct contact with the top metal contact 253, and the conductive pad 280b extends through the second passivation layer 274 of the first passivation structure 276 and its bottom surface is in direct contact with the top surface of the second conductor plate 270 of the MIM capacitor 272. That is, the conductive pads 280a and 280b have different heights, and a height of the conductive pad 280a is greater than a height of the conductive pad 280b. In a third alternative embodiment represented by FIG. 17B, the conductive pad 280a stops on the top surface of the first conductor plate 262a and does not extend through the first passivation layer 258 and the etch stop layer 256, and the conductive pad 280b stops on the top surface of the second conductor plate 270. In a fourth alternative embodiment represented by FIG. 17C, the conductive pad 280a stops on the top surface of the first conductor plate 262a and does not extend through the first passivation layer 258 and the etch stop layer 256, and the conductive pad 280b extends through the first passivation structure 276 and is in direct contact with the top metal contact 255.

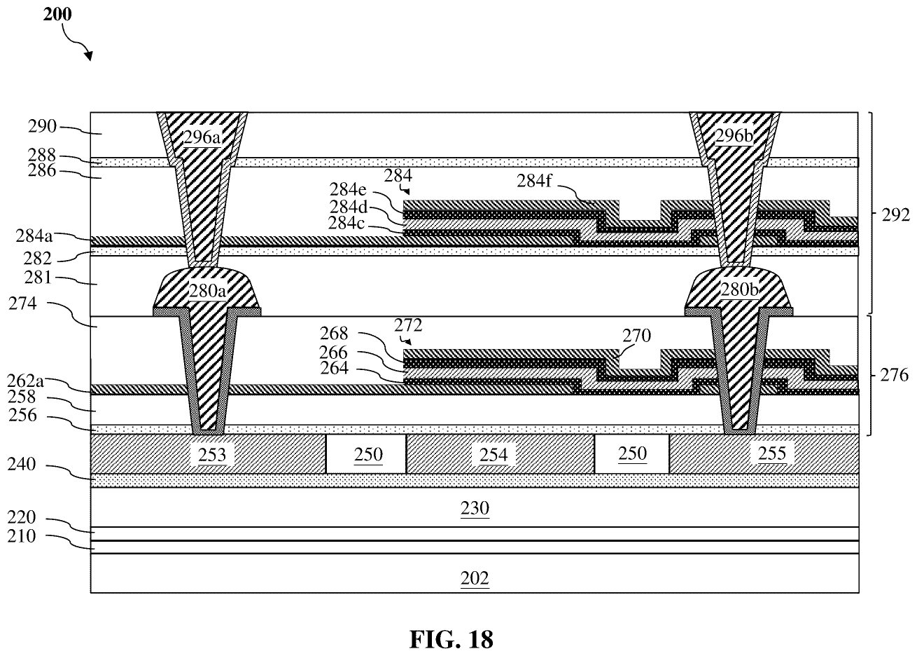

In some other alternative embodiments as represented by FIG. 18, after forming the first insulation layer 264, the high-K dielectric layer 266, and the second insulation layer 268 of the first MIM capacitor 272, a combination of lithography and etching processes may be performed to pattern the first insulation layer 264, the high-K dielectric layer 266 and the second insulation layer 268. Sidewall surfaces of the patterned first insulation layer 264, the patterned high-K dielectric layer 266 and the patterned second insulation layer 268 are vertically aligned with a sidewall surface of the second conductor plate 270. In some embodiments, same processes may be applied to the insulation layer 284c, the high-K dielectric layer 284d and the insulation layer 284e of the second MIM capacitor 284. In some other embodiments, only one of the first and second MIM capacitors 272 and 284 have the patterned dielectric structure (e.g., the combination of the first insulation layer 264, the high-K dielectric layer 266 and the second insulation layer 268; or the combination of the insulation layer 284c, the high-K dielectric layer 284d and the insulation layer 284e).

In the above embodiments, to substantially improve the TDDB related performance, all conductor plates of a MIM capacitor are separated from adjacent high-K dielectric layer(s) by a corresponding ALD-formed metal oxide layer. For example, for the first MIM capacitor 272, as depicted in FIG. 8, the first conductor plate 262a is separated from the high-K dielectric layer 266 by the ALD-formed metal oxide layer (i.e., the first insulation layer 264), and the second conductor plate 270 is spaced apart from the high-K dielectric layer 266 by the ALD-formed metal oxide layer (i.e., the second insulation layer 268); for the second MIM capacitor 284, as depicted in FIG. 12, the bottom conductor plate 284a is separated from the high-K dielectric layer 284d by the ALD-formed metal oxide layer (i.e., the insulation layer 284c), and the top conductor plate 284f is spaced apart from the high-K dielectric layer 284d by the ALD-formed metal oxide layer (i.e., the insulation layer 284e).

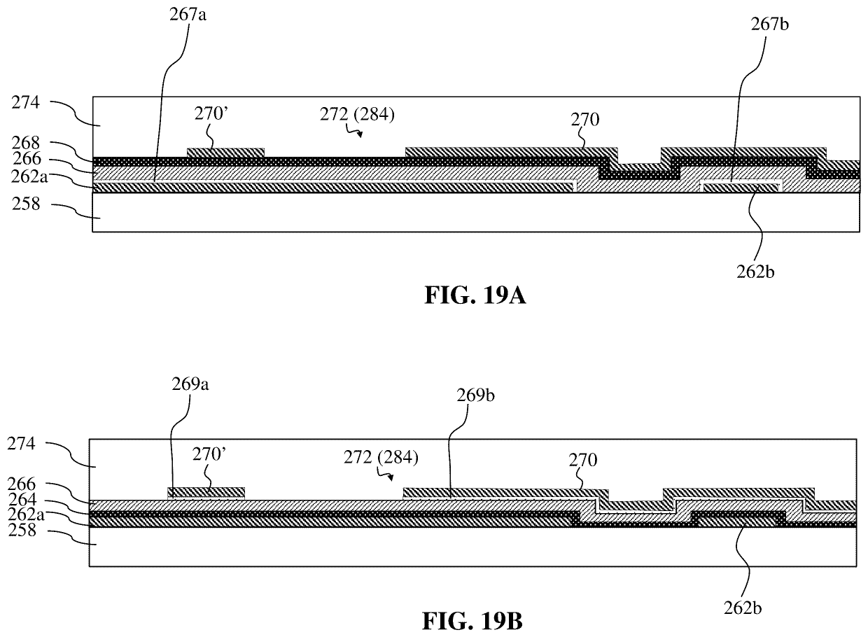

In some alternative embodiments as represented by FIG. 19A and FIG. 19B, one of the conductor plates of the MIM capacitor 272/284 is separated from an adjacent high-K dielectric layer by an ALD-formed metal oxide layer, while another one of the conductor plates of the MIM capacitor 272/284 is separated from an adjacent high-K dielectric layer by a natively-formed metal oxide layer which is not formed by a deposition process. In more detail, as depicted in FIG. 19A, a first alternative structure of the first MIM capacitor 272 is illustrated as an example. The method of forming the first alternative structure of the first MIM capacitor 272 include performing operations in blocks 106, 110, 112, and 114 of method 100, and does not include performing operations in block 108. That is, after forming the first conductor plate 262a and the dummy conductive feature 262b, the high-K dielectric layer 266 is conformally deposited on the semiconductor structure 200, including on top and sidewall surfaces of the first conductor plate 262a and the dummy conductive feature 262b, and a portion of the top surface of the first passivation layer 258 not covered by the first conductor plate 262a and the dummy conductive feature 262b. After forming the high-K dielectric layer 266, the second insulation layer 268 and the second conductor plate 270 are then formed. The metal element of the first conductor plate 262a and the dummy conductive feature 262b may react with oxygen provided by the high-K dielectric layer 266 formed thereon to form corresponding metal oxide layers at their interfaces. A metal oxide layer 267a is formed at the interface between the first conductor plate 262a and the high-K dielectric layer 266, and a metal oxide layer 267b is formed at the interface between the dummy conductive feature 262b and the high-K dielectric layer 266. Other portions of the bottom surface of the high-K dielectric layer 266 are in direct contact with the first passivation layer 258. Since the metal oxide layer 267a and the metal oxide layer 267b are formed by incomplete chemical reaction, the metal oxide layer 267a and the metal oxide layer 267b may be non-stoichiometric metal-oxides filled with vacancies, and film qualities of the metal oxide layer 267a and the metal oxide layer 267b are not as good as the film quality of the ALD-formed metal oxide layer 268. In an embodiment, the density (i.e., number/area) of vacancies of the metal oxide layer 267a/267b is greater than the density (i.e., number/area) of vacancies of the ALD-formed metal oxide layer 268. For embodiments in which the first conductor plate 262a and the dummy conductive feature 262b are formed of TiN and the high-K dielectric layer 266 is formed of HZO, the metal oxide layer 267a and the metal oxide layer 267b may include TiOₓ, where x is less than 2. For embodiments in which the first conductor plate 262a and the dummy conductive feature 262b are formed of aluminum and the high-K dielectric layer 266 is formed of HZO, the metal oxide layer 267a and the metal oxide layer 267b may include Al_{z}O_{y}, where a ratio of y to x is less than 3/2.

FIG. 19B depicts a second alternative structure of the first MIM capacitor 272. The method of forming the second alternative structure of the first MIM capacitor 272 includes performing operations in blocks 106, 108, 110, and 114 of method 100, and does not include performing operations in block 112. That is, after forming the first conductor plate 262a and the dummy conductive feature 262b, the first insulation layer 264, and the high-K dielectric layer 266 as described with reference FIG. 1, the second conductor plate 270 and the dummy conductive feature 270′ are then formed on the high-K dielectric layer 266. For similar reasons described above, the metal element of the second conductor plate 270 and the dummy conductive feature 270′ may react with oxygen provided by the high-K dielectric layer 266 formed thereunder to form corresponding metal oxide layers at their interfaces.

A metal oxide layer 269a is formed at the interface between the dummy conductive feature 270′ and the high-K dielectric layer 266, and a metal oxide layer 269b is formed at the interface between the second conductor plate 270 and the high-K dielectric layer 266. Other portions of the top surface of the high-K dielectric layer 266 are in direct contact with the second passivation layer 274. In this depicted example, the second passivation layer 274 also directly contacts the sidewall surfaces of the dummy conductive feature 270′, the metal oxide layer 269a, the second conductor plate 270, and the metal oxide layer 269b.

Since the metal oxide layers 269a and 269b are formed by incomplete chemical reaction, the metal oxide layers 269a and 269b may be non-stoichiometric metal-oxides filled with vacancies, and film qualities of the metal oxide layers 269a and 269b are not as good as the film quality of the ALD-formed metal oxide layer 264. In an embodiment, the density (i.e., number/area) of vacancies of the metal oxide layer 269a/269b is greater than the density (i.e., number/area) of vacancies of the ALD-formed metal oxide layer 264. For embodiments in which the second conductor plate 270 and the dummy conductive feature 270′ are formed of TiN and the high-K dielectric layer 266 is formed of HZO, the metal oxide layers 269a and 269b may include TiOₓ, where x is less than 2. For embodiments in which the second conductor plate 270 and the dummy conductive feature 270′ are formed of aluminum and the high-K dielectric layer 266 is formed of HZO, the metal oxide layers 269a and 269b may include Al_{z}O_{y}, where a ratio of y to x is less than 3/2. It is noted that the second MIM capacitor 284 may also have the first alternative structure and second alternative structure similar to those of the first MIM capacitor 272. Any combination of one of the three structures of the first MIM capacitor 272 and one of the three structures of the second MIM capacitor 284 are within the scope of the present disclosure. It is also noted that, each of the first MIM capacitor 272 and the second MIM capacitor 284 may include any other suitable number of conductor plates.

Although not intended to be limiting, one or more embodiments of the present disclosure provide many benefits to a semiconductor structure and the formation thereof. For example, the present disclosure provides metal-insulator-metal (MIM) capacitors having an ALD-formed metal oxide layer disposed between a conductor and an adjacent high-K dielectric layer to prevent the formation of a non-stoichiometric metal oxide layer. As a result, TDDB performance of the metal-insulator-metal capacitors may be improved. In some embodiments, forward bias breakdown voltage of the metal-insulator-metal capacitor may also be increased. Thus, the overall performance and reliability of the metal-insulator-metal capacitors may be advantageously improved.

The present disclosure provides for many different embodiments. Semiconductor structures and methods of fabrication thereof are disclosed herein. In one exemplary aspect, the present disclosure is directed to a method. The method includes forming a first metal-insulator-metal (MIM) capacitor over a substrate, wherein the forming of the first MIM capacitor comprises depositing a first conductive material layer over the substrate, the first conductive material layer comprising a first metal element, patterning the first conductive material layer to form a first conductor plate over the substrate, conformally depositing a first dielectric layer over the substrate and on the first conductor plate, the first dielectric layer comprising the first metal element, forming a first high-K dielectric layer on the first dielectric layer, conformally depositing a second dielectric layer over the substrate and on the first high-K dielectric layer, the second dielectric layer comprising a second metal element, and forming a second conductor plate over the second dielectric layer, the second conductor plate comprises the second metal element. The method further comprises forming a second metal-insulator-metal (MIM) capacitor over the first MIM capacitor.

In some embodiments, the first metal element may include aluminum, and the first dielectric layer may include Al₂O₃. In some embodiments, the second metal element may include titanium, and the first dielectric layer may include TiO₂. In some embodiments, the first high-K dielectric layer may include hafnium-zirconium oxide (HZO). In some embodiments, the second metal element may be different than the first metal element. In some embodiments, the forming of the second MIM capacitor may include forming a third conductor plate comprising a third metal element, depositing a second high-K dielectric layer on the third conductor plate, the second high-K dielectric layer comprising oxygen, conformally depositing a third dielectric layer over the substrate and on the second high-K dielectric layer, and forming a fourth conductor plate on the third dielectric layer, wherein the fourth conductor plate and the third dielectric layer comprise a same fourth metal element. In some embodiments, the oxygen of the second high-K dielectric layer may react with the third metal element of the third conductor plate and form a non-stoichiometric metal oxide layer disposed between the second high-K dielectric layer and the third conductor plate. In some embodiments, the method may also include after the forming of the first MIM capacitor, forming a first passivation layer over the first MIM capacitor, forming a first conductive feature extending through first passivation layer to electrically connect to the first conductor plate and forming a second conductive feature extending through first passivation layer to electrically connect to the second conductor plate, forming a second passivation layer over the first conductive feature and the second conductive feature, after the forming of the second MIM capacitor, forming a third passivation layer over the second MIM capacitor, forming a third conductive feature extending through the third passivation layer to electrically connect to the third conductor plate and the first conductive feature, and forming a fourth conductive feature extending through the third passivation layer to electrically connect to the fourth conductor plate and the second conductive feature. In some embodiments, a ratio of a thickness of the first dielectric layer to a thickness of the first high-K dielectric layer may be in a range between 1/10 and 1/2.

In another exemplary aspect, the present disclosure is directed to a method. The method includes forming a first conductive layer over a substrate, performing a first atomic layer deposition (ALD) process to form a first insulation layer directly on the first conductive layer, conformally forming a high-K dielectric layer on the first insulation layer, performing a second atomic layer deposition (ALD) process to form a second insulation layer over the high-K dielectric layer, and forming a second conductive layer directly on the second insulation layer, wherein the first conductive layer may include aluminum, and the first insulation layer may include Al₂O₃.

In some embodiments, the second conductive layer may include aluminum, and the second insulation layer may include Al₂O₃. In some embodiments, the second conductive layer may include titanium nitride, and the second insulation layer may include TiO₂. In some embodiments, the method may also include forming a passivation structure over the second conductive layer, wherein the passivation structure may include a metal-insulator-metal (MIM) capacitor having a bottom conductor plate and a top conductor plate separated from the bottom conductor plate by a multi-layer dielectric structure. In some embodiments, the multi-layer dielectric structure may include a first metal oxide dielectric layer having a fixed stoichiometric ratio and in direct contact with and disposed on the bottom conductor plate, wherein the first metal oxide dielectric layer and the bottom conductor plate comprise a same metal element. The multi-layer dielectric structure may include a second metal oxide dielectric layer having a fixed stoichiometric ratio and in direct contact with and disposed under the top conductor plate, wherein the second metal oxide dielectric layer and the top conductor plate comprise a same metal element. In some embodiments, the method may also include forming a first conductive feature in direct contact with the first conductive layer and forming a second conductive feature in direct contact with the second conductive layer. In some embodiments, a height of the first conductive feature may be different than a height of the second conductive feature.

In yet another exemplary aspect, the present disclosure is directed to a semiconductor structure. The semiconductor structure includes a first metal-insulator-metal (MIM) capacitor over a substrate and comprising a first conductor plate, a conformal first metal oxide insulation layer over the substrate and on the first conductor plate, a conformal second metal oxide insulation layer over the conformal first metal oxide insulation layer, and a second conductor plate over and in direct contact with the conformal second metal oxide insulation layer and vertically overlapped with the first conductor plate, wherein the first conductor plate includes aluminum, and the first metal oxide insulation layer includes Al₂O₃.

In some embodiments, the semiconductor structure may also include a high-K dielectric layer disposed vertically between the first metal oxide insulation layer and the second metal oxide insulation layer. In some embodiments, the second conductor plate may include titanium, and the second metal oxide insulation layer may include TiO₂. In some embodiments, the semiconductor structure may also include a first passivation layer over the first MIM capacitor and comprising a planar top surface and a second metal-insulator-metal (MIM) capacitor over the first passivation layer. The second metal-insulator-metal (MIM) capacitor may include a bottom conductor plate over the first passivation layer, a conformal metal oxide dielectric layer over the bottom conductor plate and the first passivation layer, a conformal high-K dielectric layer over the conformal metal oxide dielectric layer, and a top conductor plate over the conformal high-K dielectric layer and vertically overlapped with the bottom conductor plate, wherein an entirety of a bottom surface of the top conductor plate is spaced apart from the conformal high-K dielectric layer by a non-stoichiometric metal oxide layer, the top conductor plate and the non-stoichiometric metal oxide layer comprise a same metal element. The semiconductor structure may also include a second passivation layer over the second MIM capacitor and in direct contact with a sidewall surface of the bottom conductor plate and a sidewall surface of the non-stoichiometric metal oxide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first metal-insulator-metal (MIM) capacitor over a substrate, the first MIM capacitor comprises a first conductor plate and a second conductor plate over and spaced apart from the first conductor plate;
depositing a first passivation layer over the first MIM capacitor;
forming a first conductive pad extending through the first passivation layer to couple to the first conductor plate;
forming a second conductive pad extending through the first passivation layer to couple to the second conductor plate;
depositing a second passivation layer over the first conductive pad, the second conductive pad, and the first passivation layer;
forming a second metal-insulator-metal (MIM) capacitor over the second passivation layer, the second MIM capacitor comprises a third conductor plate and a fourth conductor plate over and spaced apart from the third conductor plate;
forming a first bonding structure extending through the third conductor plate to couple to the first conductive pad; and
forming a second bonding structure extending through the fourth conductor plate to couple to the second conductive pad.

2. The method of claim 1, wherein substrate comprises a first lower contact and a second lower contact embedded in a dielectric layer, and the first conductive pad is electrically coupled to the first lower contact.

3. The method of claim 1, wherein a height of the first conductive pad is greater than a height of the second conductive pad.

4. The method of claim 3, wherein a bottom surface of the first conductive pad is below a bottom surface of the second conductive pad.

5. The method of claim 1, wherein the first conductive pad comprises a first portion over the first passivation layer, a second portion extending through the first passivation layer, and a third portion under the first passivation layer.

6. The method of claim 5, wherein the second conductive pad comprises a first portion over the first passivation layer and a second portion extending into the first passivation layer.

7. The method of claim 1, wherein the first MIM capacitor further comprises a first dielectric structure disposed between the first conductor plate and the second conductor plate, the first dielectric structure comprises:
a first insulation layer;
a high-k dielectric layer over the first insulation layer; and
a second insulation layer over the high-k dielectric layer.

8. The method of claim 7, wherein the first insulation layer and the first conductor plate comprises a first metal element, the second insulation layer and the second conductor plate comprises a second metal element different from the first metal element.

9. The method of claim 8, wherein the high-k dielectric layer comprises a third metal element different from the first metal element and the second metal element.

10. A method, comprising:
receiving a substrate comprising a first lower contact and a second lower contact embedded in a dielectric layer;
forming a first metal-insulator-metal (MIM) capacitor over a substrate, the first MIM capacitor comprises a first conductor plate and a second conductor plate over and spaced apart from the first conductor plate;
depositing a first passivation layer over the first MIM capacitor;
forming a first conductive pad extending through the first passivation layer and the first conductor plate to couple to the first lower contact;
forming a second conductive pad extending through the first passivation layer without extending through the second conductor plate, wherein the second conductive pad is electrically coupled to the second conductor plate;
forming a second metal-insulator-metal (MIM) capacitor over the first MIM capacitor, the second MIM capacitor comprises a third conductor plate and a fourth conductor plate over and spaced apart from the third conductor plate;
forming a first bonding structure extending through the third conductor plate to couple to the first conductive pad; and
forming a second bonding structure extending through the fourth conductor plate to couple to the second conductive pad.

11. The method of claim 10, further comprising:
depositing a first passivation layer over the second MIM capacitor;
depositing an etch stop layer over the first passivation layer; and
depositing a second passivation layer over the etch stop layer, wherein the first and second bonding structures extends through the first passivation layer, the etch stop layer, and the second passivation layer.

12. The method of claim 11, wherein a portion of the first bonding structure extends on a top surface of the etch stop layer.

13. The method of claim 11, wherein the first bonding structure is disposed on the first conductive pad.

14. The method of claim 10, wherein the second MIM capacitor further comprises a dielectric structure disposed between the third conductor plate and the fourth conductor plate, the dielectric structure comprises:
a first insulation layer;
a high-k dielectric layer over the first insulation layer; and
a second insulation layer over the high-k dielectric layer.

15. The method of claim 14, wherein the first insulation layer and the third conductor plate comprises a first metal element, the second insulation layer and the fourth plate comprises a second metal element different from the first metal element.

16. The method of claim 15, wherein the high-k dielectric layer comprises a third metal element different from the first metal element and the second metal element.

17. A method, comprising:
depositing a first conductive layer over a substrate;
patterning the first conductive layer to form a first conductor plate of a metal-insulator-metal (MIM) capacitor and a first dummy plate;
conformally depositing a first insulation layer over the first conductor plate and the first dummy plate;
conformally depositing a second insulation layer over the first insulation layer;
conformally depositing a third insulation layer over the second insulation layer, wherein a composition of the second insulation layer is different from composition of the first and third insulation layers;
forming a second conductor plate of the MIM capacitor and a second dummy plate over the third insulation layer;
forming a first contact pad extending through the second dummy plate and the first conductor plate; and
forming a second contact pad over and electrically coupled to the second conductor plate, wherein a bottom surface of the first contact pad is lower than a bottom surface of the second contact pad.

18. The method of claim 17, wherein the MIM capacitor is a first MIM capacitor, and the method further comprises:
forming a second MIM capacitor over the first MIM capacitor;
forming a first bonding structure extending through a first conductor plate of the second MIM capacitor and electrically coupled to the first contact pad; and
forming a second bonding structure extending through a second conductor plate of the second MIM capacitor and electrically coupled to the second contact pad.

19. The method of claim 18, wherein the second MIM capacitor further comprises a multi-layer dielectric structure disposed between the first conductor plate of the second MIM capacitor and the second conductor plate of the second MIM capacitor, wherein the multi-layer dielectric structure comprises:
a first dielectric layer,
a high-k dielectric layer on the first dielectric layer; and
a second dielectric layer on the high-k dielectric layer, wherein the high-k dielectric layer comprises hafnium-zirconium oxide (HZO).

20. The method of claim 19, wherein the first conductor plate of the second MIM capacitor comprises aluminum, the first dielectric layer comprises aluminum oxide, the second conductor plate of the second MIM capacitor comprises titanium nitride, and the second dielectric layer comprises titanium oxide.
